(19) United States
(12) Patent Application Publication
(10) Pub. No.: US 2007/0271057 A1
(43) Pub. Date: Nov. 22, 2007

(54) Inspection method of semiconductor integrated circuit and semiconductor

(76) Inventors: Hiroaki Shiroyama, Kyoto (JP); Keiichi Tsumura, Hyogo (JP)

Correspondence Address: MCDERMOTT WILL & EMERY LLP, 600 13TH STREET, NW, WASHINGTON, DC, 20005-3096, US

(21) Appl. No.: 11/798,807

(22) Filed: May 17, 2007

(30) Foreign Application Priority Data
May 17, 2006 (JP) 2006-137645

(51) Int. Cl. G06F 19/00; G01R 31/00

(52) U.S. Cl. 702/117; 702/1; 702/127; 702/108

(57) ABSTRACT

It is detected with a detecting circuit whether or not a signal outputted from an output terminal and a signal inputted to an output buffer are coincident with each other, and a retaining circuit retains a detection result by the detecting circuit.

### BACKGROUND OF THE INVENTION

1. Field of the Invention

The present invention relates to a semiconductor integrated circuit, more particularly to a technology for detecting failures such as short circuit between output/input terminals and a power supply/GND and short circuit between adjacent terminals, which are mounted on a semiconductor integrated circuit mounted on a substrate.

2. Description of the Related Art

As downsizing of devices such as an in-vehicle camera, a mobile camera and a digital still camera have been advanced, and a system has been increasingly sophisticated in recent years, increase of number of semiconductors mounted on a semiconductor substrate and high density thereof are accelerated. Further, number of terminals in the semiconductor integrated circuit is increasing in response to the trend of one chip, and a package shape has been reduced, and such a package that is provided with terminals on a rear surface thereof as an example of a chip size package (CSP) and cannot be easily monitored after it is mounted, is often used. As a result, it is very difficult to find failures due to a poor packaging on the mounting substrate.

The IEEE 1149.1 boundary scan standard, that aims to facilitate an inspection of the packaging substrate, is known as a conventional technology. Further, in a semiconductor integrated circuit recited in H05-188117 of the Japanese Patent Documents, a comparison detection signal is generated inside the semiconductor integrated circuit based on a particular pattern signal inputted to the semidconductor integrated circuit via another semiconductor integrated circuit in a previous stage, and then the particular pattern signal and the comparison detection signal are compared to each other, so that it is confirmed if there is any defect in wirings on the substrate.

However, in these conventional examples wherein, since the semiconductor integrated circuits in the previous and latter stages are necessary for the inspection, the respective semiconductor integrated circuits are inevitably set in a very complicated manner, and it takes a large amount of time for the inspection to be completed. In fact, the conventional constitutions have not yet been widely available. Further, in the case where input signals necessary to be judged are all fixed to the “L” level on the substrate, the signals pass the inspection, which makes it impossible to detect the failures.

### SUMMARY OF THE INVENTION

Therefore, a main object of the present invention is to allow each of a plurality of semiconductor integrated circuits mounted on a packaging substrate to independently and easily detect such failures only by itself as short circuit between input/output terminals and a power supply/GND and short circuit between adjacent terminals on the substrate.

A semiconductor integrated circuit according to the present invention comprises:

an internal circuit;

an output buffer;

an output terminal for outputting a signal outputted by the internal circuit outside via the output buffer; and

an external failure detecting circuit, wherein

the external failure detecting circuit comprises:

a detecting circuit for detecting whether or not a signal outputted from the output terminal and a signal inputted to the output buffer are coincident with each other; and

a retaining circuit for retaining a result of the detection by the detecting circuit.

In addition, an exclusive OR circuit may constitute the detecting circuit, and a register may constitute the retaining circuit. Those detect the failures such as the short circuit between the output terminal and the power supply/GND and the short circuit between the adjacent terminals on the substrate.

In an inspection method of the semiconductor integrated circuit corresponding to it, the internal circuit in the semiconductor integrated circuit is operated in an actual operation mode, and thereafter a value of a non-coincidence detection signal retained by the retaining circuit is read so that a state of the output terminal is judged.

In the foregoing constitution, the signal outputted by operation of the internal circuit is inputted to the detecting circuit from an input side of the output buffer, and the signal appearing at the output terminal connected to an output side of the output buffer is inputted to the detecting circuit. Then, these signals are compared to each other in the detecting circuit to detect if they are coincident with each other, and the detection result (non-coincidence detection signal) is retained through the retaining circuit. In a normal operation wherein the failures such as the short circuit between the output terminal and the power supply/GND and the short circuit between the adjacent terminals on the substrate are not generated, the detection result by the detecting circuit (non-coincidence detection signal) remains inactive because these signals are coincident with each other. In an abnormal state wherein the short circuits or the like are generated, on the contrary, transition of the signal on the input side of the output buffer is not correctly transmitted to the output side of the output buffer, the detection result (non-coincidence detection signal) by the detecting circuit becomes active because and these signals are not coincident with each other. Thus, detection with or without error at the output terminal in the relevant semiconductor integrated circuit can be self-checked by the external failure detecting circuit provided inside. Further, the error judgment can be easily carried out because the self-check can be realized without the intervention of other semiconductor integrated circuits provided before and after the relevant semiconductor integrated circuit.

In the foregoing constitution, there is an embodiment that the semiconductor integrated circuit further comprises

a storage device for storing testing data; and

a selecting device for alternatively selecting the signal outputted by the internal circuit or the testing data stored in the storage device and outputting the selecting result to the output buffer.

Furthermore, the storage device may be constituted with a register, and the selecting device may be constituted with a selecting device main body and a register for switching the selecting device main body.

In an inspection method of the semiconductor integrated circuit corresponding to it, the testing data is alternatively selected from a plurality of testing data outputted by the storage device in the semiconductor integrated circuit, and after that

the detection result retained by the retaining circuit is read so that the state of the output terminal is judged.

If it is constituted like this, the judgment can be made by the external failure detecting circuit after the testing data having a logic different from that of the output signal from the internal circuit is stored in the storage device, and then the stored data is selected by the selecting device. Further, detailed responses can be easily taken through setting the testing data in the judgment of the abnormal state at a plurality of output terminals.

More specifically, in the case where there is a plurality of actual operation modes in applying it to the plurality of output terminals, the output terminals as a target to be checked may not be operated, it may happen that the output terminals to be inspected are not operated at one try. Under the circumstances, it becomes necessary to perform the inspection as often as necessary while selecting the operation mode at the same time, which takes significantly much time. Therefore, when the foregoing constitution is applied to each terminal, reference data of the plurality of output terminals can be simultaneously set irrespective of the operation mode so that the output terminals can be judged at one try.

In the case where the adjacent terminals output signals similar to each other, the short circuit cannot be detected even if it is generated between the relevant terminals. In that case, phases of the testing data at the adjacent terminals are reversed to each other (“1”←→“0”), the judgment can be easily made.

Additionally, a semiconductor integrated circuit according to the present invention comprises:

a storage device for storing testing data;

an input terminal;

an internal circuit;

an input buffer inserted between the input terminal and the internal circuit;

a detecting circuit for detecting whether or not a signal outputted by the input buffer and the testing data stored in the storage device are coincident with each other;

a retaining circuit for retaining a result of the detection by the detecting circuit; and

a switch for controlling supply of the testing data to the input buffer.

Farther, the storage device may be constituted with a register, the detecting circuit may be constituted with an exclusive OR circuit, and the switch may be constituted with a tristate buffer and a register for controlling conduction of the tristate buffer. Herewith, the failures such as the short circuit between the input terminal and the power supply /GND and shortage between the adjacent terminals on the substrate are detected.

In an inspection method of the semiconductor integrated circuit corresponding to this, the testing data is alternatively selected from a plurality of testing data outputted by the storage device, and then the detection result retained by the retaining circuit is read so that a state of the input terminal is judged.

In the foregoing constitution, the testing data from the storage device is inputted to the detecting circuit, and simultaneously the testing data is transmitted to an input side of the input buffer (connection line between the input buffer and the input terminal) via the switch, and further, inputted to the detecting circuit from the input buffer. Then, it is judged with the detecting circuit whether or not the testing data stored in the storage device and the testing data inputted via the input terminal are coincident with each other. The judgment result is retained with the retaining circuit. In a normal operation wherein the failures such as the short circuit between the input terminal and the power supply/GND, and the short circuit between the adjacent terminals on the substrate are not generated, and the detection result by the detecting circuit remains inactive because these testing data are coincident with each other. In an abnormal state wherein the short circuits or the like are generated, on the contrary, transition of the testing data is not correctly transmitted to the output side of the output buffer, and these testing data are not coincident with each other. Therefore, the detection result becomes active. Thus, detection with or without error at the input terminal in the relevant semiconductor integrated circuit can be self-checked in the built-in external failure detecting circuit. Further, the error judgment can be easily achieved because such the self-check can be carried out without the intervention of other semiconductor integrated circuits provided before and after the relevant semiconductor integrated circuit.

In any of the foregoing semiconductor integrated circuits, there is an embodiment that the external failure detecting circuit may further comprise an irregular pulse eliminating device for eliminating an irregular pulse generated in the detection result.

If it is constituted like this, even though there is a time lag between the two signals or the two testing data inputted to the detecting circuit, and the irregular pulse during a very short time period is thereby generated in the non-coincidence detection signal, the irregular pulse is eliminated by the irregular pulse eliminating device so that the non-coincidence detection signal having a correct waveform can be transmitted to the retaining circuit. As a result, a wrong detection can be avoided in the detection of the failures such as the short circuit.

Additionally, there is an embodiment that The semiconductor integrated circuit according to the present invention may further comprises a monitor for monitoring a potential of the output terminal, wherein the detecting circuit detects presence or absence of the pulse based on a variation of the potential detected by the monitor.

Furthermore, as a preferable embodiment of the foregoing constitution, the monitor is constituted with an input buffer, and the detecting circuit comprises: a flip-flop to which an output signal of the input buffer and a signal outputted by the output terminal are inputted; and an AND circuit to which an output signal of the flip-flop and an inversion signal of the output signal of the flip-flop are inputted, wherein the retaining circuit is a register.

In an inspection method of the semiconductor integrated circuit corresponding to this, the internal circuit in the semiconductor integrated circuit is operated in an actual operation mode, and the detection result retained by the retaining circuit is read so that a state of the output terminal is judged.

In the foregoing constitution, when a pulse is applied to the output terminal from outside, the applied pulse is monitored by the monitor and detected by the detecting circuit, and then, the detection result is retained by the retaining circuit. Thus, presence or absence of the external pulse at the output terminal can be self-inspected by the external failure detecting circuit in the semiconductor integrated circuit. Further, the error judgment can be easily achieved because the self-check can be realized without the intervention of other semiconductor integrated circuits provided before and after the relevant semiconductor integrated circuit.

According to the present invention, the failures such as the short circuit between the output terminal/input terminal of the semiconductor integrated circuit mounted on the packaging substrate and the power supply/GND on the substrate, and the short circuit between the adjacent terminals can be easily detected without the intervention of other semiconductor integrated circuits provided before and after the relevant semiconductor integrated circuit.

The present invention is effective as a technology for easily detecting failures such as short circuit in one of a plurality of semiconductor integrated circuits mounted on a packaging substrate.

### BRIEF DESCRIPTION OF THE DRAWINGS

These and other objects as well as advantages of the invention will become clear by the following description of preferred embodiments of the invention. A number of benefits not recited in this specification will come to the attention of those skilled in the art upon the implementation of the present invention.

FIG. 1 is a block circuit diagram showing a constitution of a semiconductor integrated circuit according to a preferred embodiment 1 of the present invention.

FIG. 2 is an operation waveform chart when there is not any problem in the semiconductor integrated circuit according to the preferred embodiment 1.

FIG. 3 is an operation waveform chart when short circuit is generated in the semiconductor integrated circuit according to the preferred embodiment 1.

FIG. 4 is a block circuit diagram showing a constitution of a semiconductor integrated circuit according to a preferred embodiment 2 of the present invention.

FIG. 5 is an operation waveform chart when there is not any problem in the semiconductor integrated circuit according to the preferred embodiment 2.

FIG. 6 is an operation waveform chart when short circuit is generated in the semiconductor integrated circuit according to the preferred embodiment 2.

FIG. 7 is a block circuit diagram showing a constitution of a semiconductor integrated circuit according to a preferred embodiment 3 of the present invention.

FIG. 8 is a block circuit diagram showing a constitution of a semiconductor integrated circuit according to a preferred embodiment 4 of the present invention.

### DETAILED DESCRIPTION OF THE INVENTION

Hereinafter, preferred embodiments of a semiconductor integrated circuit and an inspection method thereof according to the present invention are described in detail referring to the drawings. In the preferred embodiments described below, an example with respect to one of output terminals and input terminals provided in the semiconductor integrated circuit is explained, however, it can be applied to two and more terminals. In the drawings, like references denote the same components.

### Preferred Embodiment 1

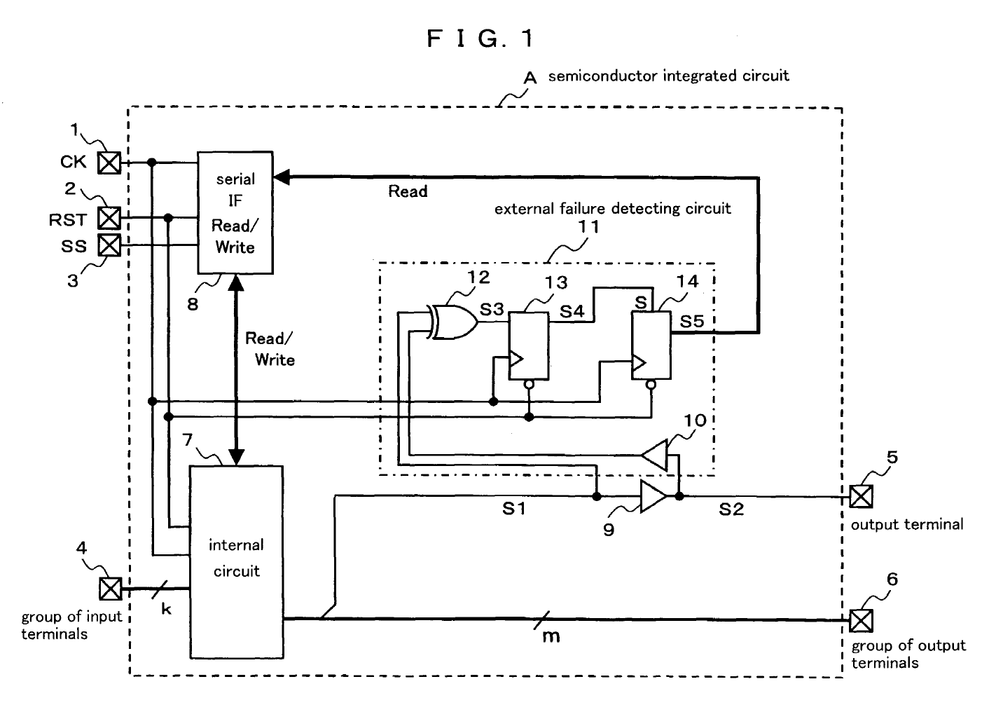

FIG. 1 is a block circuit diagram showing a constitution of a semiconductor integrated circuit according to a preferred embodiment 1 of the present invention. Referring to reference symbols shown in FIG. 1, A denotes a semiconductor integrated circuit, 1 denotes a clock CK input terminal, 2 denotes an input terminal of a reset signal RST, 3 denotes an input terminal of a serial signal SS for serial I/F, 4 denotes k pieces of input terminals, 5 denotes an output terminal to be inspected, 6 denotes m pieces of output terminals, 7 denotes an internal circuit, 8 denotes a register read/write circuit for the serial I/F, 9 denotes an output buffer inserted between an output terminal of the internal circuit 7 and the output terminal 5 of the semiconductor integrated circuit A, 10 denotes an input buffer branched from a connection line between the output buffer 9 and the output terminal 5, 11 denotes an external failure detecting circuit, 12 denotes a detecting circuit in which an EXOR circuit is adopted, 13 denotes a flip-flop, which functions as an irregular pulse eliminating device for eliminating an irregular pulse appearing in a non-coincidence detection signal S3 by the detecting circuit 12, and 14 denotes a register for retaining the non-coincidence detection signal S3 by the detecting circuit 12.

The semiconductor integrated circuit A comprises the internal circuit 7 as an actual operation circuit and the register read/write circuit 8 for executing read and write operations to a register of the internal circuit 7. Signals from the group of input terminals 4, the clock Ck and the reset signal RST are inputted to the internal circuit 7. Meanwhile, a signal is outputted from the internal circuit 7 to the group of output terminals 6 and the output terminal 5 to be inspected. The signal is outputted to the output terminal 5 via the output buffer 9.

The clock CK and the reset signal RST are inputted to the register read/write circuit 8. The register read/write circuit 8 reads and writes a register value of the internal circuit 7 based on information of the serial signal SS. I/O buffers of the group of input terminals 4, the group of output terminals 6, the clock CK and the reset signal RST are not shown.

The external failure detecting circuit 11 comprises a detecting circuit 12, a flip-flop 13 and a register 14. The detecting circuit 12 compares a reference signal S1 outputted from the internal circuit 7 so as to be applied to an input side of the output buffer 9, and a reference signal S2 obtained when the signal S1 has passed through the output buffer 9 and the input buffer 10. When it is known from a result of the comparison that these signals are not coincident with each other, the detecting circuit 12 sets the non-coincidence detection signal S3 to “1”, and outputs it. The input buffer 10 improves a drive performance. The flip-flop 13 eliminates the irregular pulse during a very short time period in the non-coincidence detection signal S3 outputted from the detecting circuit 12. The register 14 is set to the “1” level when an output signal S4 from the flip-flop 13 is “1”, and retains “1” until the reset signal RST is inputted. The flip-flop 13 is also initialized to “0” by the reset signal RST. The register read/write circuit a reads a value S5 retained by the register 14 in the external failure detecting circuit 11 in accordance with an instruction of the serial signal SS and judges if there is any abnormality at the output terminal 5.

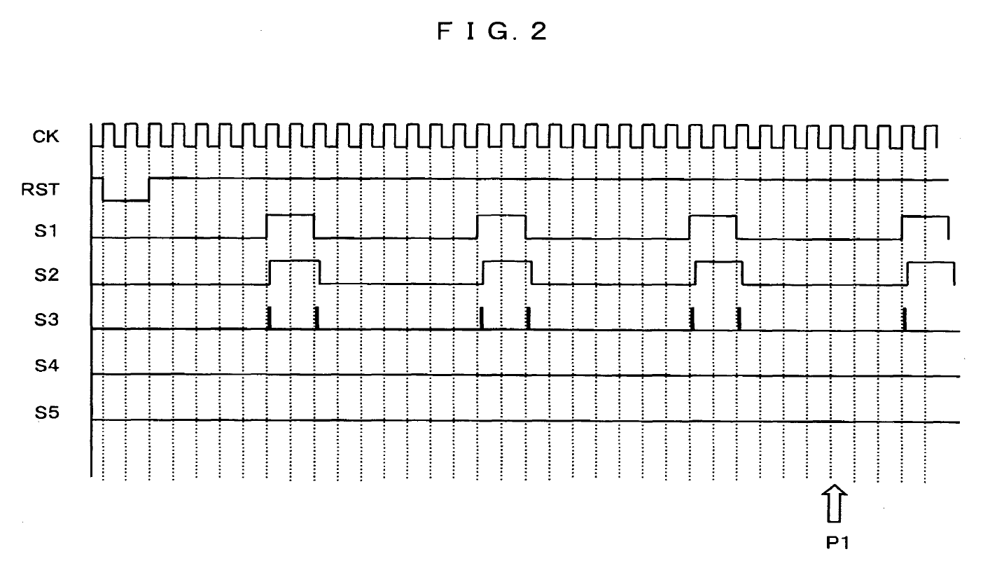

Next, an operation of the semiconductor integrated circuit A according to the present preferred embodiment thus constituted is described. First, the operation in the normal state is described referring to a waveform chart shown in FIG. 2. In FIG. 2, S1 denotes a reference signal generated in the internal circuit 7 in the actual operation, S2 denotes a signal for monitoring the state of the output terminal S5, S3 denotes a non-coincidence detection signal outputted by the detecting circuit 12, S4 denotes an irregular pulse elimination signal outputted by the flip-flop 13, S5 denotes a value retained by the register 14, and P1 denotes a register read point.

In an initial resetting operation, the flip-flop 13 and the register 14 are reset to “0” by the rising edge of the reset signal RST. In the actual operation, the reference signal S1 serves as a reference of the signal outputted from the internal circuit 7 and applied to the input side of the output buffer 9. A waveform of the reference signal S1 and a waveform of the reference signal S2 at the output terminal 5 are compared to each other in the detecting circuit 12. The reference signal S2 is an inspecting signal obtained when the reference signal S1 has passed through the output buffer 9 and the input buffer 10.

When the reference signal S1 rises in the normal operation, the reference signal S2 thereafter rises after a slight delay. When the reference signal S1 falls in the normal operation, the reference signal S2 thereafter falls after a slight delay. A result of the comparison by the detecting circuit 12 is shown in a waveform of the non-coincidence detection signal S3. Because there is a slight time difference between the signals S1 and S2 arriving at the detecting circuit 12, the irregular pulse is generated in the non-coincidence detection signal S3. However, the irregular pulse has a time width smaller than a cycle of the clock CK, and the non-coincidence detection signal S3 retains “0” in other than the irregular pulse. Therefore, the output state of the flip-flop 13 is not inverted, and the irregular pulse elimination signal S4 outputted by the flip-flop 13 maintains “0” at the time of the reset. In other words, the irregular pulse is eliminated in the flip-flop 13.

Because the irregular pulse elimination signal “4 outputted by the flip-flop 13 is at the “0” level, the register 14 is not set, and the value S5 thereof maintains “0” at the time of the reset. Therefore, the value S5 of the register 14 is “0” at the register read point P1, which is read by the register read/write circuit 8 in accordance with the instruction of the serial signal SS.

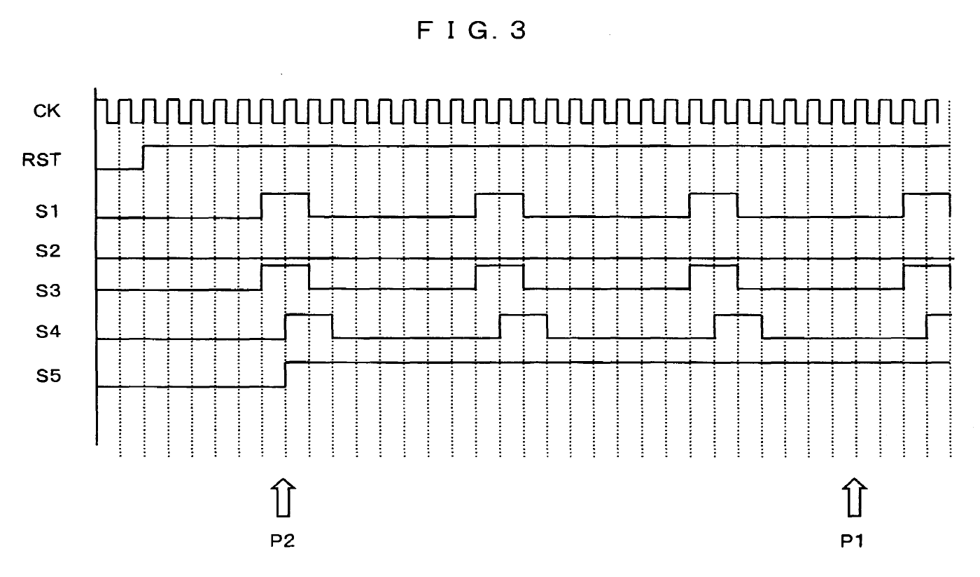

Next, the operation in the abnormal state (short circuit or the like) is described referring to a waveform chart shown in FIG. 3. In the drawing, it is assumed that the output terminal 5 is short-circuited with respect to GND, and the waveform of the reference signal S2 at the output terminal 5 is fixed to “0”.

Because the reference signal S2 remains “0” due to the short-circuit with respect to the GND despite the rising edge of the reference signal S1, the non-coincidence detection signal S3 by the detecting circuit 12 rises to “1”. When the reference signal S1 falls, the non-coincidence signal S3 falls to “0”. At the time, a period when the non-coincidence detection signal S3 is “1” corresponds to a period when the reference signal S1 is “1”. The period has a time width that is substantially larger compared to the cycle of the clock CK. Accordingly, the irregular pulse elimination signal S4 outputted from the flip-flop 13 also rises when the clock CK rises with the delay of 1T, while keeping the non-coincidence detection signal S3 as “1”. Since “1” of the non-coincidence detection signal S3 is not the irregular pulse, “1” is transmitted from the input side to the output side of the flip-flop 13, as a result, the irregular pulse elimination signal S4 by the flip-flop 13 rises. The register 14 is thereby set, and the value S5 thereof shifts from “0” to “1”. The shift to “1” in the output (S5) of the register 14 thus generated indicates the short circuit with respect to the GND at the output terminal 5. In FIG. 3, the failure (short circuit) is detected at a point P2.

When the non-coincidence detection signal S3 falls in response to the rise of the next clock CK, the irregular pulse elimination signal S4 by the flip-flop 13 also falls, however, the value S5 of the register 14 is retained at “1” because the state of the register 14 is not changed unless the reset signal RST is inputted. The value S5 of the register 14 is retained at “1” at the register read point P1, which is read by the register read/write circuit 8. The register read/write circuit 8 which reads and writes the register value of the internal circuit 7 based on the information of the serial signal SS receives the input of “1” from the register 14 at the register read point P1, and thereby detects the circuit abnormality in the semiconductor integrated circuit A.

As described above, through the use of the fact that the value of the register 14 at the register read point P1 is different depending on the presence or absence of the failure (short circuit or the like), it is judged whether or not there is any failure. More specifically, the judgment is OK when the value of the register 14 is read as “0” by the register read/write circuit 8 at the register read point P1 when the serial signal SS is inputted, while the judgment is NG when the read value is “1”. The judgment is made in a similar manner in the case of the short circuit with respect to the power supply.

The method of reading the register 14 can be realized in a similar manner in a circuit comprising a microcomputer (CPU) I/F in place of the register read/write circuit 8 of the serial IF. When a similar circuit configuration is adopted, a plurality of output terminals can be checked in a similar manner.

According to the present preferred embodiment based on the foregoing constitution and inspection method, the failures such as the short circuit between the output terminal and the power supply/GND, and the short circuit between the adjacent terminals can be easily detected in a short period of time without the intervention of other semiconductor integrated circuits provided before and after the relevant semiconductor integrated circuit on the packaging substrate.

### Preferred Embodiment 2

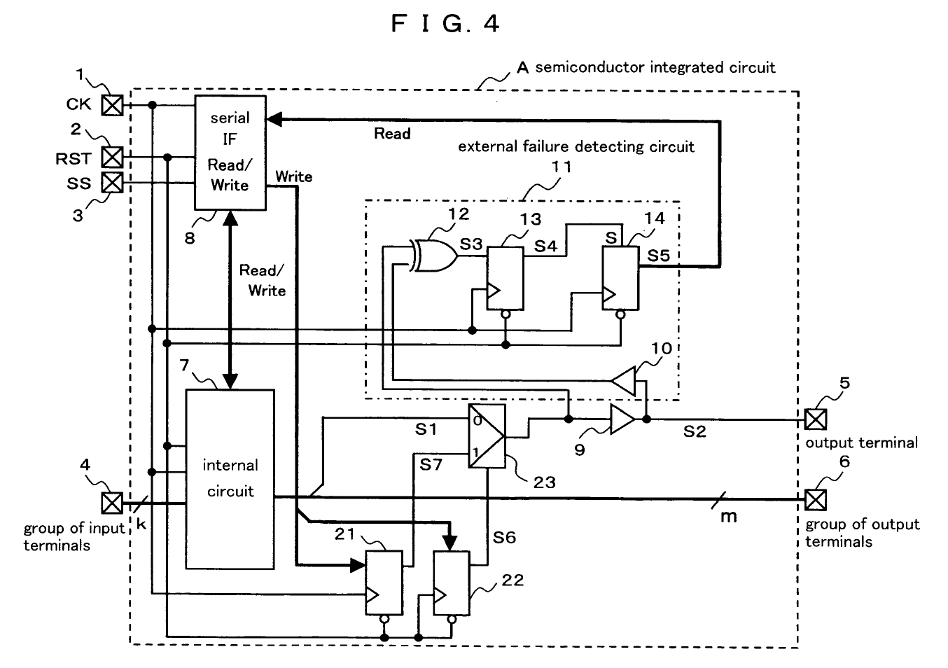

FIG. 4 is a block circuit diagram showing a constitution of a semiconductor integrated circuit according to a preferred embodiment 2 of the present invention. Referring to reference numerals shown in FIG. 4, 21 denotes a register for setting testing data, 22 denotes a register for setting an inspection mode, and 23 denotes a selecting device main body. A value S6 that is outputted from the register 22 for setting the inspection mode is set in the selecting device main body 23 so that either reference signal S1 outputted from the internal circuit 7 or a value S7 of the register 21 for setting the testing data is alternatively selected in before the output buffer 9. In this description, the signal S1 is selected when the value S6 of the register 22 for setting the inspection mode is “0”, while the signal S7 is selected when the value S6 is “1”. The register 21 for setting the testing data corresponds to the storage device, and the register 22 for setting the inspection mode and the selecting device main body 23 correspond to the selecting device.

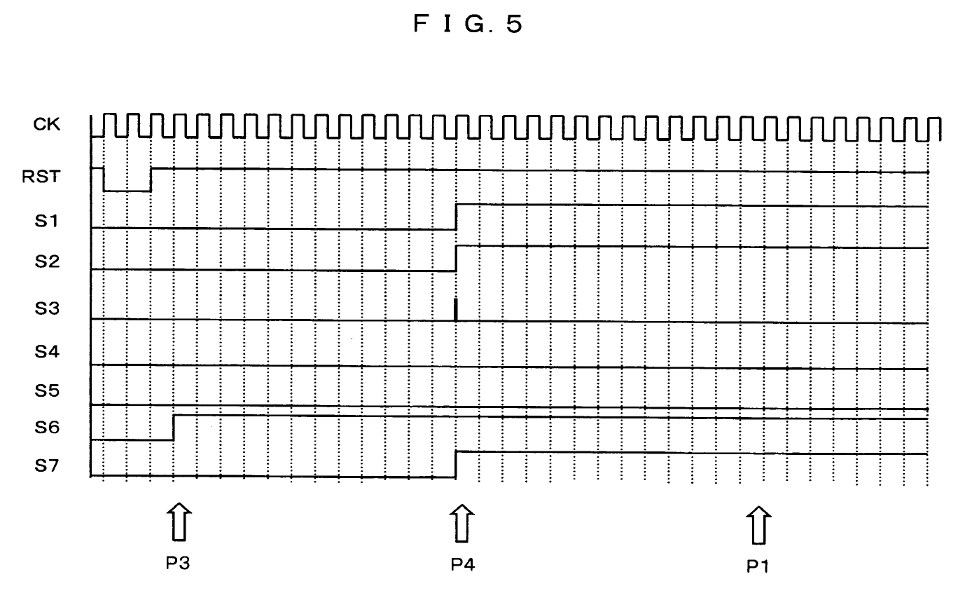

Next, an operation of the semiconductor integrated circuit A according to the present preferred embodiment thus constituted is described. First, the operation in the normal state is described referring to a waveform chart shown in FIG. 5. In FIG. 5, P3 denotes an inspection mode switching point, and P4 denotes a testing data switching point. In an initial resetting operation, the register 21 for setting the testing data and the register 22 for setting the inspection mode are reset to “0”. After the reset is released, the register read/write circuit 8 sets the value S6 (“1”) to the register 22 for setting the inspection mode at the inspection mode switching point P3. As a result, the selecting device main body 23 selects and outputs the value S7 of the register 21 for setting the testing data. At the time, the value S7 is “0”, and the selecting device main body 23 selects the value S7 (“0”) as the reference signal S1 and outputs the selected value S7 to the output buffer 9. The reference signal S2 outputted by the output buffer 9, to which the reference signal S1[=value S7 (“0”)] is inputted, is outputted to the output terminal 5 and also transmitted to the detecting circuit 12. The detecting circuit 12 compares the reference signal S2[=value S7 (“0”)] to the reference signal S1[=value S7 (“0”)] to each other.

At the testing data switching point P4 when a certain period of time has passed, the register read/write circuit 8 writes the value “1” in the register 21 for setting the testing data. As a result, the selecting device main body 23 selects and outputs the value S7 of the register 21 for setting the testing data. At the time, the value S7 is “1”, and the selecting device main body 23 selects the value S7 (“1”) as the reference signal S1 and transmits the selected value S7 to the output buffer 9. The reference signal S2 outputted by the output buffer 9, to which the reference signal S1 [=value S7 (“1”)] is inputted, is outputted to the output terminal 5 and also transmitted to the detecting circuit 12. The detecting circuit 12 compares the reference signal S2 [=value S7 (“1”)] to the reference signal S1 [=value S7 (“1”)] to each other.

Thus, “0” and “1” are sequentially transmitted to the input side of the output buffer 9 as the value S7 of the register 21 for setting the testing data. Any subsequent step is similar to that of the preferred embodiment 1. Because the short circuit with respect to the GND is not generated at the output terminal 5, the value S5 of the register 14 in the external failure detecting circuit 11 is retained at the value “0” under a reset state.

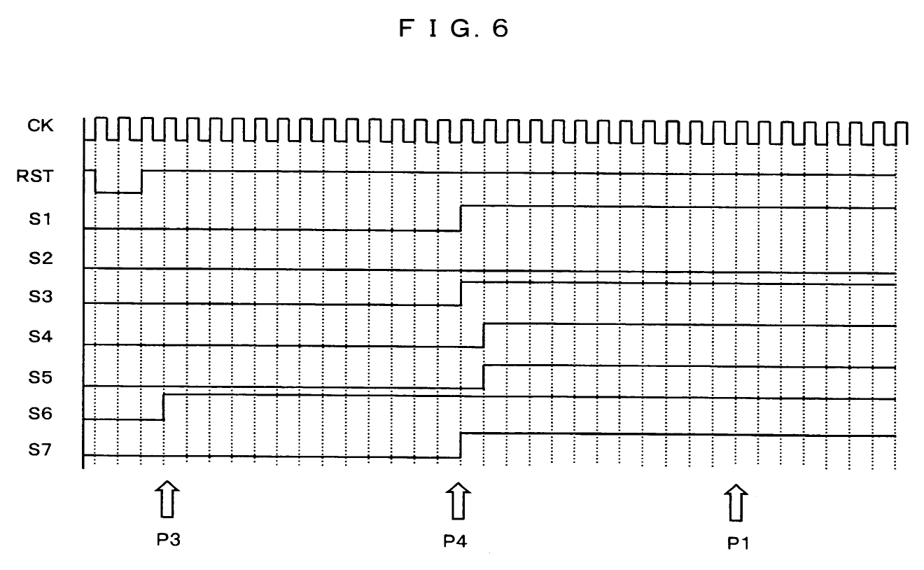

Next, the operation in the abnormal state (short circuit or the like) is described referring to a waveform chart shown in FIG. 6. The description below is based on the assumption that the short circuit of the output terminal 5 with respect to the GND is generated, and the waveform of the reference signal S2 at the output terminal 5 is fixed to “0”.

In a manner similar to the description of the normal operation, the register read/write circuit 8 sets the value S6 (“1”) in the register 22 for setting the inspection mode. As a result, the selecting device main body 23 selects and outputs the value S7 of the register 21 for setting the testing data. At the time, the value S7 is “0” immediately after the inspection mode switching point P3, and “1” immediately after the testing data switching point P4.

When the value S7 is “0”, the value S5 of the register 14 in the external failure detecting circuit 11 remains the initial value, which is “0”, even if the output terminal 5 is short-circuited with respect to the GND. Meanwhile, when the value S7 is “1”, the value S5 of the register 14 is inverted to “1” if the output terminal 5 is short-circuited with respect to the GND. Thus, the value S5 of the register 14 at the register read point P1 is different each other depending on the present or absence of the short circuit as described referring to FIGS. 4 and 5.

In the case of the present preferred embodiment 1, assuming that there is a plurality of actual operation modes to be applied to a plurality of output terminals, the state, that the output terminals to be checked may not be operating at the same time, is generated. In such a case, it takes a large amount of time because the inspection has to be implemented as often as necessary while the modes are selected at the same time. On the contrary, in the present preferred embodiment, the reference data of the plurality of output terminals can be simultaneously set without depending on the modes, the judgment can be thereby made at one try.

Additionally, there is a case that the adjacent terminals output signals of the same logic, it is not possible to detect the short circuit when it is generated between the terminals in the constitution of the preferred embodiment 1. Correspondingly, according to the present preferred embodiment, the data of the register 21 for setting the testing data at the adjacent terminals are set to be reverse each other (“1”←→“0”), so that the failures at the adjacent terminals can be judged and detected even if the adjacent terminals output the signals of the same logic.

### Preferred Embodiment 3

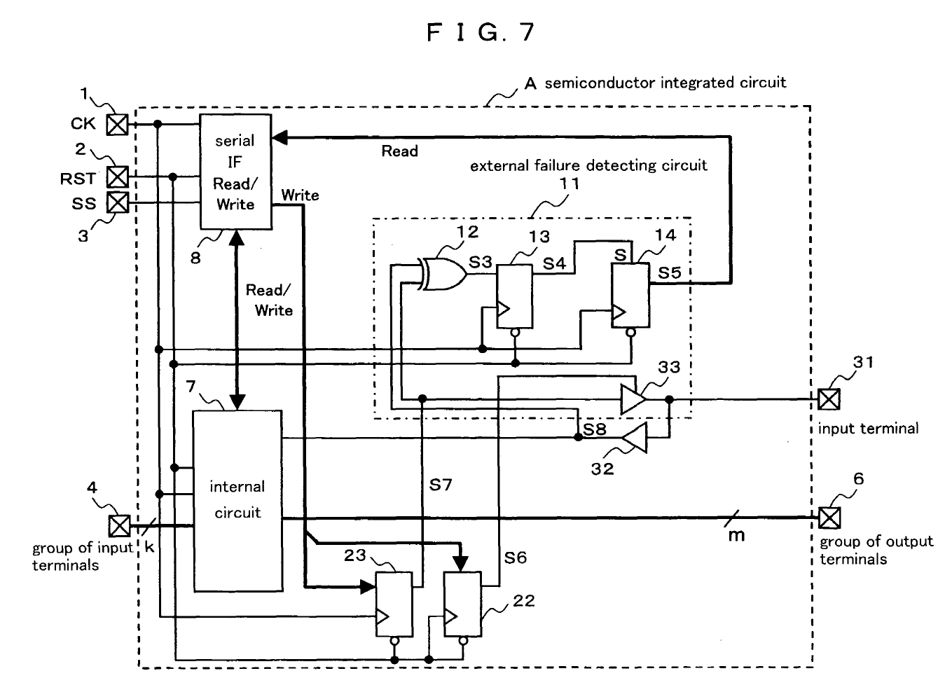

FIG. 7 is a block circuit diagram illustrating a constitution of a semiconductor integrated circuit according to a preferred embodiment 3 of the present invention, wherein the technology according to the preferred embodiment 2 is applied to an input terminal. The below description focuses on differences between the present preferred embodiment and the preferred embodiment 2. Referring to reference numerals shown in FIG. 7, 31 denotes an input terminal, 32 denotes an input buffer, and 33 denotes a tristate buffer. The input terminal 31 is connected to the internal circuit 7 via the input buffer 32. An output terminal of the register 21 for setting the testing data is connected to the detecting circuit 12 and an input side of the tristate buffer 33. An output side of the tristate buffer 33 is connected to a connection line between the input terminal 31 and the input buffer 32. The register 22 for setting the inspection mode is connected to a control terminal of the tristate buffer 33. Further, an output side of the input buffer 32 is connected to another-end input of the detecting circuit 12. The register 22 for setting the inspection mode and the tristate buffer 33 correspond to the switch.

Next, an operation of the semiconductor integrated circuit A according to the present preferred embodiment thus constituted is described. When the value S6 of the register 22 for setting the inspection mode is set to “1” at the time of the inspection, the tristate buffer 33 is conducted. The value S7 of the register 21 for setting the testing data is directly applied to one of the input terminals of the detecting circuit 12. The value S7 is transmitted to a connection point between the input terminal 31 and the input buffer 32 via the tristate buffer in the conducted state, and then, applied to the other input terminal of the detecting circuit 12 via the input buffer 32.

If short circuit to the GND is not generated and it is normal at the input terminal 31, the value S5 of the register 14 remains “0” since the signals supplied to the detecting circuit 12 are coincident with each other. In the case where the short circuit to the GND is generated at the input terminal 31, the following state is generated. In short, the value S5 of the register 14 remains “0” when the value S7 of the register 21 for setting the testing data is “0”, while a value S8 passed through the input buffer 32 is “0” when the value s7 is “1”. Accordingly, the signals supplied to the detecting circuit 12 are not coincident with each other, and the value S5 of the register 14 is inverted to “1”. In addition, it is assumed that an output terminal of the semiconductor integrated circuit in the previous stage on the packaging substrate is controlled to be in an impedance state. According to the present preferred embodiment, the failure can be detected at the input terminal as well in a manner similar to the preferred embodiment 2.

### Preferred Embodiment 4

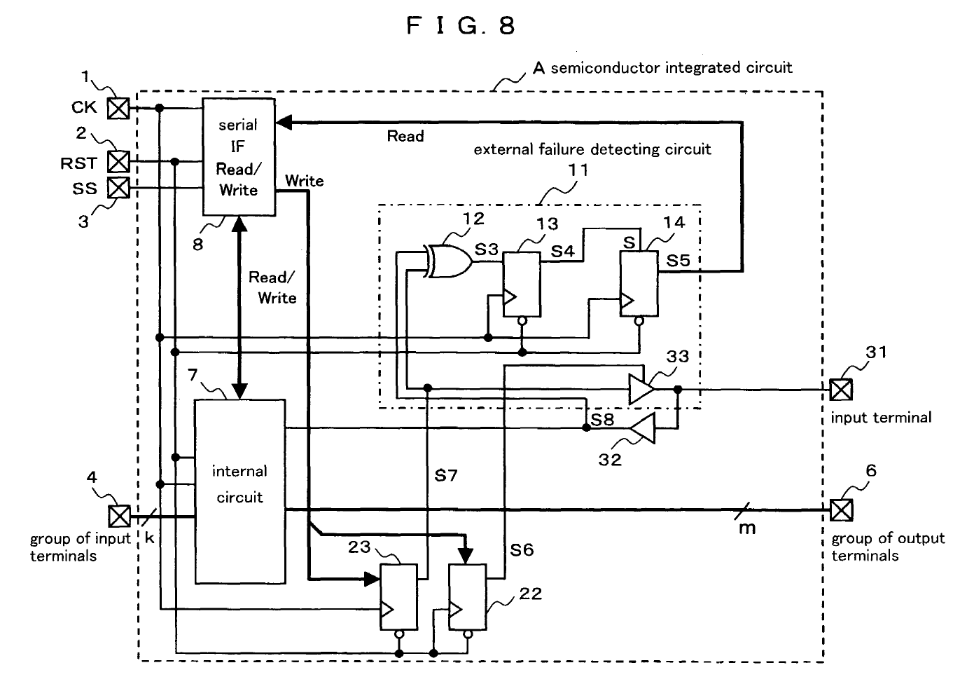

FIG. 8 is a block circuit diagram showing a constitution of a semiconductor integrated circuit according to a preferred embodiment 4 of the present invention, wherein the constitution of the external failure detecting circuit 11 recited in the preferred embodiments 1 and 2 is changed. Referring to reference numerals shown in FIG. 8, 41 denotes a flip-flop of the toggle type, and 42 denotes an AND circuit. An output of the input buffer 10 is connected to the flip-flop 41 and the AND circuit 42, and an output of the flip-flop 41 is connected to the AND circuit 42 in an inverted manner. Further, an output of the AND circuit 42 is connected to a set input of a register 43 of the toggle type. The input buffer 10 corresponds to the monitor for monitoring the potential of the output terminal 5, the flip-flop 41 and the AND circuit 42 correspond to the detecting circuit for detecting presence or absence of an outer-side pulse at the output terminal 5 obtained through the monitoring, and the register 43 corresponds to the retaining circuit for retaining a pulse detection signal S10 by the detecting circuit.

Next, an operation of the semiconductor integrated circuit A according to the present preferred embodiment thus constituted is described. An output signal S9 of the input buffer 10 and a signal obtained when the output signal S9 is delayed by 1T and inverted in the flip-flop 41 are inputted to the AND circuit 42. When the pulse appears at the output terminal 5 in the normal operation where the short circuit of the output terminal 5 with respect to the GND and the power supply is not generated, the rising edge of the pulse is detected in the AND circuit 42. As a result, the pulse detection signal S10 outputted by the AND circuit 42 is “1”, and the register 43 is set to “1”. In other words, “1” is written in the register 43 in the absence of the failure (short circuit or the like). Meanwhile, in the state where the short circuit of the output terminal 5 with respect to the GND and the power supply is generated on the packaging substrate, the pulse detection signal S10 outputted by the AND circuit 42 is “0”, and the register 43 is set to “0”. Thus, the failure can be judged because the set value of the register 43 is different between the cases with and without the short circuit. However, in the case where the value of the register 43 is read by the register read/write circuit 8, adversely in the preferred embodiments 1 and 2, the judgment is OK when the output of the register 43 is “1”, while the judgment is NG when the output is “0”. However, the case where output operations of “H”“L” are carried out at the adjacent output terminals is made exception.

Though preferred embodiments of this invention have been described in detail, it will be understood that various modifications may be made therein, and it is intended to cover in the appended claims all such modifications as fall within the true spirit and scope of this invention.

What is claimed is:

1. A semiconductor integrated circuit comprising:
an internal circuit;
an output buffer;
an output terminal for outputting a signal outputted by the internal circuit outside via the output buffer; and
an external failure detecting circuit, wherein
the external failure detecting circuit comprises:
a detecting circuit for detecting whether or not a signal outputted from the output terminal and a signal inputted to the output buffer are coincident with each other; and
a retaining circuit for retaining a result of the detection by the detecting circuit.

2. The semiconductor integrated circuit as claimed in claim 1, wherein
the detecting circuit is an exclusive OR circuit, and the retaining circuit is a register.

3. The semiconductor integrated circuit as claimed in claim 1, further comprising:
a storage device for storing testing data; and
a selecting device for alternatively selecting the signal outputted by the internal circuit or the testing data stored in the storage device so as to output the selecting result to the output buffer.

4. The semiconductor integrated circuit as claimed in claim 3, wherein
the storage device is a register, and
the selecting device comprises:
a selecting device main body; and
a register for switching an output of the selecting device main body.

5. A semiconductor integrated circuit comprising:
a storage device for storing testing data;
an input terminal;
an internal circuit;
an input buffer inserted between the input terminal and the internal circuit;
a detecting circuit for detecting whether or not a signal outputted by the input buffer and the testing data stored in the storage device are coincident with each other;
a retaining circuit for retaining a result of the detection by the detecting circuit; and
a switch for controlling supply of the testing data to the input buffer.

6. The semiconductor integrated circuit as claimed in claim 5, wherein
the storage device is a register
the detecting circuit is an exclusive OR circuit, and the switch comprises:
a tristate buffer; and
a register for controlling conduction of the tristate buffer.

7. The semiconductor integrated circuit as claimed in claim 1, wherein
the external failure detecting circuit further comprises an irregular pulse eliminating device for eliminating an irregular pulse generated in the detection result.

8. A semiconductor integrated circuit comprising:
an internal circuit; and
an external failure detecting circuit, wherein
the external failure detecting circuit comprises:
an output terminal for outputting a signal outputted by the internal circuit outside;
a detecting circuit for detecting presence or absence of a pulse in the signal outputted by the output terminal; and
a retaining circuit for retaining a result of the detection by the detecting circuit.

9. The semiconductor integrated circuit as claimed in claim 8, further comprising a monitor for monitoring a potential of the output terminal, wherein
the detecting circuit detects the presence or the absence of the pulse based on a variation of the potential detected by the monitor.

10. The semiconductor integrated circuit as claimed in claim 8, wherein
the monitor consists of an input buffer, and
the detecting circuit comprises:
a flip-flop to which an output signal of the input buffer and a signal outputted by the output terminal are inputted; and
an AND circuit to which an output signal of the flip-flop and an inversion signal of the output signal of the flip-flop are inputted, and
the retaining circuit is a register.

11. An inspection method of a semiconductor integrated circuit, wherein
the internal circuit of the semiconductor integrated circuit as claimed in claim 1 is operated in an actual operation mode, and then
a value of a non-coincidence detection signal retained by the retaining circuit is read so that a state of the output terminal is judged.

12. An inspection method of a semiconductor integrated circuit, wherein
the testing data is alternatively selected from a plurality of testing data outputted by the storage device in the semiconductor integrated circuit as claimed in claim 3, and thereafter
the detection result retained by the retaining circuit is read so that a state of the output terminal is judged.

13. An inspection method of a semiconductor integrated circuit, wherein
the testing data is alternatively selected from a plurality of testing data outputted by the storage device in the semiconductor integrated circuit as claimed in claim 5, and then
the detection result retained by the retaining circuit is read so that a state of the input terminal is judged.

14. An inspection method of a semiconductor integrated circuit, wherein
the internal circuit in the semiconductor integrated circuit as claimed in claim 8 is operated in an actual operation mode, and the
the detection result retained by the retaining circuit is read so that a state of the output terminal is judged.
